(19) United States
(12) Patent Application Publication
(10) Pub. No.: US 2023/0298863 A1
(43) Pub. Date: Sep. 21, 2023

(54) SEMICONDUCTOR MANUFACTURING APPARATUS AND SEMICONDUCTOR DEVICE MANUFACTURING METHOD

(71) Applicant: Kioxia Corporation, Tokyo (JP)

(72) Inventor: Yusuke KASAHARA, Yokkaichi Mie (JP)

(73) Assignee: Kioxia Corporation, Tokyo (JP)

(21) Appl. No.: 17/931,230

(22) Filed: Sep. 12, 2022

(30) Foreign Application Priority Data
Mar. 19, 2022 (JP) 2022-044752

(51) Int. Cl. H01J 37/32; H01L 21/3065

(52) U.S. Cl. CPC H01J 37/32449; H01J 37/32522; H01J 37/32862; H01L 21/3065; H01J 2237/002; H01J 2237/3341

(57) ABSTRACT

A semiconductor manufacturing apparatus of embodiments includes: a chamber including a top plate and a sidewall; a holder provided in the chamber holding a substrate; a first high frequency power supply applying high frequency power to the holder or the top plate; a second high frequency power supply applying high frequency power to the holder; a third high frequency power supply applying high frequency power to the top plate; a gas supply pipe supplying a gas to the chamber; and a gas discharge pipe discharging a gas from the chamber.

### CROSS-REFERENCE TO RELATED APPLICATION

This application is based upon and claims the benefit of priority from Japanese Patent Application No. 2022-044752, filed on Mar. 19, 2022, the entire contents of which are incorporated herein by reference.

### FIELD

Embodiments described herein relate generally to a semiconductor manufacturing apparatus and a semiconductor device manufacturing method.

### BACKGROUND

When a layer containing a metal element is etched by reactive ion etching, by-products containing the metal element adhere to the inner surface of the chamber. By-products adhering to the inner surface of the chamber cause the generation of particles, for example. Therefore, it is demanded to remove by-products adhering to the inner surface of the chamber by cleaning the chamber.

### BRIEF DESCRIPTION OF THE DRAWINGS

FIG. 1 is a schematic diagram of a semiconductor manufacturing apparatus of embodiments;

FIG. 2 is an explanatory diagram of an example of a semiconductor device manufacturing method of embodiments;

FIG. 3 is an explanatory diagram of an example of a semiconductor device manufacturing method of embodiments;

FIG. 4 is an explanatory diagram of an example of a semiconductor device manufacturing method of embodiments;

FIG. 5 is an explanatory diagram of an example of a semiconductor device manufacturing method of embodiments;

FIG. 6 is an explanatory diagram of an example of a semiconductor device manufacturing method of embodiments; and

FIG. 7 is an explanatory diagram of an example of a semiconductor device manufacturing method of embodiments.

### DETAILED DESCRIPTION

A semiconductor manufacturing apparatus of embodiments includes: a chamber including a top plate and a sidewall; a holder provided in the chamber holding a substrate; a first high frequency power supply applying high frequency power to the holder or the top plate; a second high frequency power supply applying high frequency power to the holder; a third high frequency power supply applying high frequency power to the top plate; a gas supply pipe supplying a gas to the chamber; and a gas discharge pipe discharging a gas from the chamber.

Hereinafter, embodiments will be described with reference to the diagrams. In the following description, the same or similar members and the like may be denoted by the same reference numerals, and the description of the members and the like once described may be omitted as appropriate.

In addition, in this specification, the term “upper” or “lower” may be used for convenience. “Upper” or “lower” is a term indicating, for example, a relative positional relationship in the diagrams. The term “upper” or “lower” does not necessarily define the positional relationship with respect to gravity.

Hereinafter, a semiconductor manufacturing apparatus and a semiconductor device manufacturing method of embodiments will be described with reference to the diagrams.

A semiconductor manufacturing apparatus of embodiments includes: a chamber including a top plate and a sidewall; a holder provided in the chamber to hold a substrate; a first high frequency power supply for applying high frequency power to the holder or the top plate; a second high frequency power supply for applying high frequency power to the holder; a third high frequency power supply for applying high frequency power to the top plate; a gas supply pipe for supplying a gas to the chamber; and a gas discharge pipe for discharging a gas from the chamber.

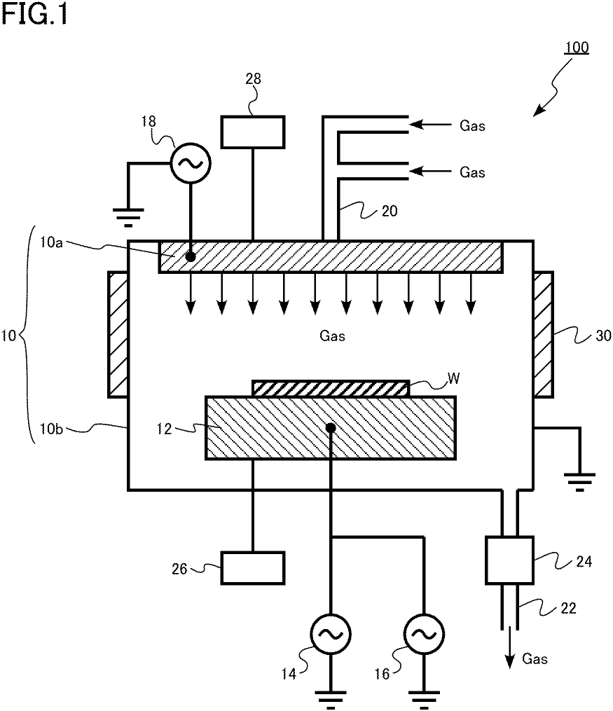

FIG. 1 is a schematic diagram of a semiconductor manufacturing apparatus of embodiments. The semiconductor manufacturing apparatus of embodiments is a reactive ion etching apparatus (RIE apparatus). The reactive ion etching apparatus of embodiments is a capacitively coupled plasma apparatus (CCP apparatus).

An RIE apparatus 100 includes, for example, a chamber 10, a holder 12, a first high frequency power supply 14, a second high frequency power supply 16, a third high frequency power supply 18, a gas supply pipe 20, a gas discharge pipe 22, an exhaust device 24, a first cooling device 26, a second cooling device 28, and a heater 30. The second cooling device 28 is an example of a cooling device.

The chamber 10 includes a shower head 10a and a sidewall 10b. The shower head 10a is an example of a top plate.

The shower head 10a is provided in the upper part of the chamber 10. The shower head 10a supplies the gas supplied from the gas supply pipe 20 into the chamber 10 in a shower shape.

The shower head 10a functions as an upper electrode. High frequency power is applied to the shower head 10a. The shower head 10a is, for example, a metal.

For example, a refrigerant flow path (not shown) is provided inside the shower head 10a. The refrigerant flow path is a void. A refrigerant for cooling the shower head 10a is supplied to the refrigerant flow path.

The sidewall 10b is electrically separated from the shower head 10a by, for example, an insulating material (not shown). The sidewall 10b is, for example, grounded.

The holder 12 is provided in the chamber 10. For example, a semiconductor wafer W is placed on the holder 12. The semiconductor wafer W is an example of a substrate.

The holder 12 includes, for example, an electrostatic chuck (not shown) on its upper surface. For example, the holder 12 attracts the semiconductor wafer W by using the electrostatic chuck.

The holder 12 functions as a lower electrode. High frequency power is applied to the holder 12. The holder 12 is, for example, a metal.

For example, a refrigerant flow path is provided inside the holder 12. The refrigerant flow path is a void. A refrigerant for cooling the holder 12 is supplied to the refrigerant flow path.

The first high frequency power supply 14 has a function of applying high frequency power to the holder 12. The first high frequency power supply 14 is connected to the holder 12. Plasma can be generated in the chamber 10 by the high frequency power applied to the holder 12 by the first high frequency power supply 14.

The high frequency power applied to the holder 12 by the first high frequency power supply 14 is, for example, equal to or more than 50 W and equal to or less than 20000 W. The oscillation frequency of the high frequency power applied to the holder 12 by the first high frequency power supply 14 is, for example, equal to or more than 10 MHz and equal to or less than 200 MHz.

The second high frequency power supply 16 has a function of applying high frequency power to the holder 12. The second high frequency power supply 16 is connected to the holder 12. By applying high frequency power to the holder 12 by the second high frequency power supply 16, the energy of ions colliding with the semiconductor wafer W is controlled. For example, by lowering the oscillation frequency, the energy of ions colliding with the semiconductor wafer W increases.

The high frequency power applied to the holder 12 by the second high frequency power supply 16 is, for example, equal to or more than 50 W and equal to or less than 20000 W. The oscillation frequency of the high frequency power applied to the holder 12 by the second high frequency power supply 16 is lower than the oscillation frequency of the high frequency power applied to the holder 12 by the first high frequency power supply 14. The oscillation frequency of the high frequency power applied by the second high frequency power supply 16 is, for example, equal to or more than 0.1 MHz and equal to or less than 30 MHz.

The third high frequency power supply 18 has a function of applying high frequency power to the shower head 10a. The third high frequency power supply 18 is connected to the shower head 10a. By applying high frequency power to the shower head 10a by the third high frequency power supply 18, the energy of ions colliding with the surface of the shower head 10a is controlled. For example, by lowering the oscillation frequency, the energy of ions colliding with the semiconductor wafer W increases.

The high frequency power applied to the shower head 10a by the third high frequency power supply 18 is, for example, equal to or more than 50 W and equal to or less than 20000 W. The oscillation frequency of the high frequency power applied to the shower head 10a by the third high frequency power supply 18 is lower than, for example, the oscillation frequency of the high frequency power applied to the holder 12 by the second high frequency power supply 16. The oscillation frequency of the high frequency power applied by the third high frequency power supply 18 is, for example, equal to or more than 0.1 MHz and equal to or less than 30 MHz.

The gas supply pipe 20 is provided above the chamber 10, for example. Gas is supplied from the gas supply pipe 20 to the chamber 10. For example, gas is introduced from the gas supply pipe 20 into the shower head 10a, and the gas is supplied from the shower head 10a into the chamber 10.

For example, etching gas or cleaning gas can be supplied from the gas supply pipe 20. The etching gas is used, for example, for etching the layer to be processed that is formed on the semiconductor wafer W. The cleaning gas is used to remove by-products produced due to etching the layer to be processed. The cleaning gas is, for example, a gas containing diketone. The cleaning gas is, for example, a gas containing hydrocarbon. The cleaning gas is, for example, a gas containing oxygen.

The gas discharge pipe 22 is provided below the chamber 10, for example. From the gas discharge pipe 22, for example, an unconsumed etching gas, an unconsumed cleaning gas, or a reaction product is discharged from the chamber 10.

The exhaust device 24 is connected to the gas discharge pipe 22. The exhaust device 24 is, for example, a vacuum pump.

The first cooling device 26 has a function of cooling the holder 12. The first cooling device 26 is, for example, a chiller.

The first cooling device 26 is connected to, for example, a refrigerant flow path provided inside the holder 12. The first cooling device 26 is used to circulate the refrigerant in the cooling flow path. The refrigerant is, for example, a fluorine-based inert liquid.

The second cooling device 28 has a function of cooling the shower head 10a. The second cooling device 28 is, for example, a chiller.

The second cooling device 28 is connected to, for example, a refrigerant flow path provided inside the shower head 10a. The second cooling device 28 is used to circulate the refrigerant in the cooling flow path. The refrigerant is, for example, a fluorine-based inert liquid.

The heater 30 is provided, for example, on the outer side of the sidewall 10b of the chamber 10. The heater 30 has a function of heating the sidewall 10b. The heater 30 is, for example, a resistance heating heater.

The semiconductor wafer W placed on the holder 12 is anisotropically etched by using the plasma generated between the shower head 10a and the holder 12 in the chamber 10.

Next, a semiconductor device manufacturing method using the semiconductor manufacturing apparatus of embodiments will be described. The semiconductor device manufacturing method of embodiments includes a cleaning method of the semiconductor manufacturing apparatus.

A semiconductor device manufacturing method of embodiments includes: loading a substrate having a first layer containing indium (In) into a chamber of a reactive ion etching apparatus including the chamber and a holder provided in the chamber to hold a substrate, the chamber including a top plate and a sidewall; placing the substrate on the holder; performing etching processes to etch the first layer; unloading the substrate out of the chamber; starting supply of a first gas containing oxygen (O) into the chamber; starting application of first high frequency power to the holder or the top plate to generate oxygen plasma in the chamber; stopping the application of the first high frequency power; stopping the supply of the first gas; starting supply of a second gas containing diketone or hydrocarbon into the chamber; and stopping the supply of the second gas.

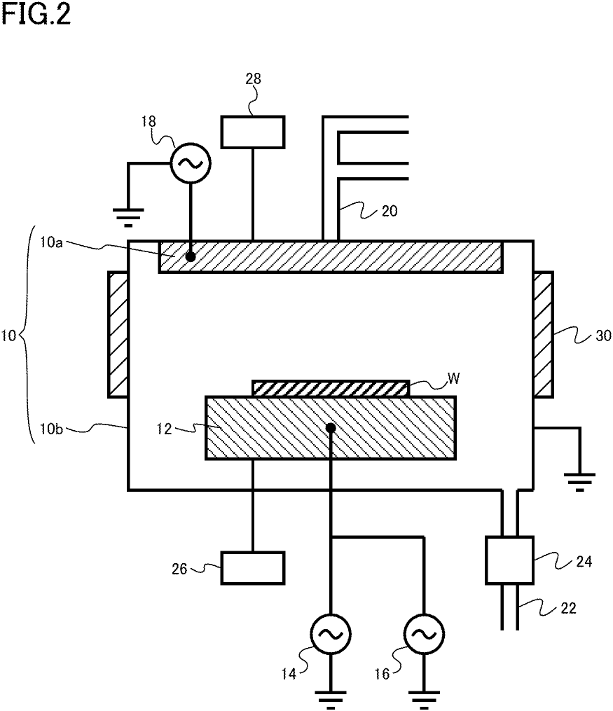

FIGS. 2 to 7 are explanatory diagrams of an example of the semiconductor device manufacturing method of embodiments.

First, the semiconductor wafer W having a first layer containing indium (In) is loaded into the chamber 10 of the RIE apparatus 100. The semiconductor wafer W is an example of a substrate. The semiconductor wafer W is, for example, a silicon substrate.

The first layer contains, for example, indium (In), tin (Sn), and oxygen (O) . The first layer is, for example, an indium tin oxide layer. The first layer contains, for example, indium (In), gallium (Ga), zinc (Zn), and oxygen (O). The first layer is, for example, an indium gallium zinc oxide layer.

The semiconductor wafer W loaded into the chamber 10 is placed on the holder 12 (FIG. 2).

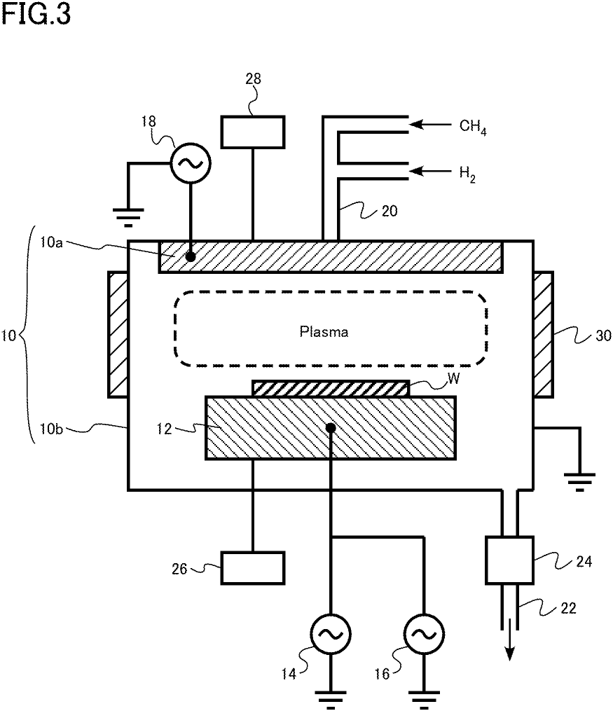

Then, etching processes for etching the first layer are performed (FIG. 3). From the gas supply pipe 20, for example, methane gas (CH₄) and hydrogen gas (H₂) are supplied into the chamber 10 as etching gases. The exhaust device 24 is operated to reduce the pressure in the chamber 10 and keep the pressure at a predetermined pressure.

Then, high frequency power is applied to the holder 12 by the first high frequency power supply 14 and the second high frequency power supply 16. The first high frequency power supply 14 mainly controls the plasma density in the chamber 10 by the high frequency power applied to the holder 12. The second high frequency power supply 16 mainly controls the Bias between the plasma and the wafer by the high frequency power applied to the holder 12. As a result, ions or radicals collide with the semiconductor wafer W to etch the first layer.

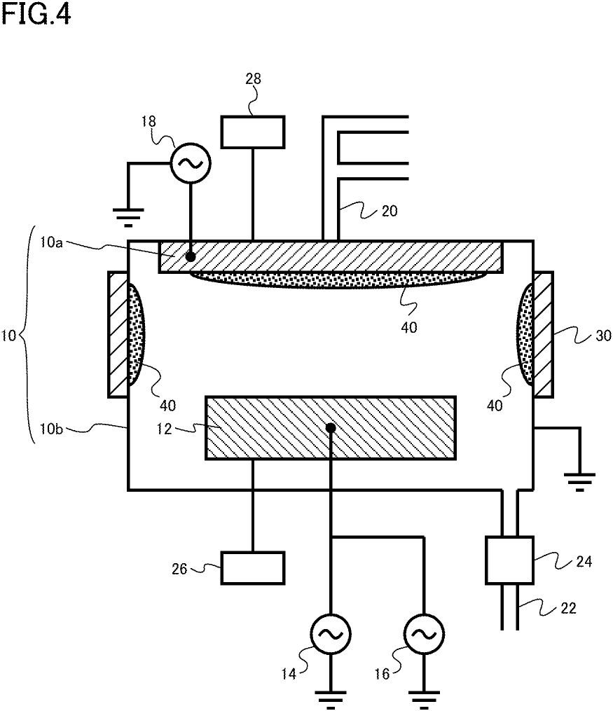

Then, the application of the high frequency power to the holder 12 is stopped to stop the supply of the etching gas. Therefore, the etching processes end. After the end of the etching processes, the semiconductor wafer W is unloaded from the chamber 10 (FIG. 4).

During the etching processes, a by-product 40 containing indium (In) adheres to the surface of the shower head 10a and the surface of the sidewall 10b. The by-product 40 containing indium is, for example, an oxide or a fluoride.

Following the etching processes, a cleaning process for removing the by-product 40 containing indium is performed.

After the end of the etching processes, a dummy wafer W′ is loaded into the chamber 10 of the RIE apparatus. The dummy wafer W′ is, for example, a silicon substrate. For example, the dummy wafer W′ protects the surface of the electrostatic chuck of the holder 12 during a cleaning process.

At the beginning of the cleaning process, the supply of oxygen gas (O₂) from the gas supply pipe 20 into the chamber 10 is started. The oxygen gas (O₂) is an example of a first gas containing oxygen (O). The exhaust device 24 is operated to keep the pressure in the chamber 10 at a predetermined pressure.

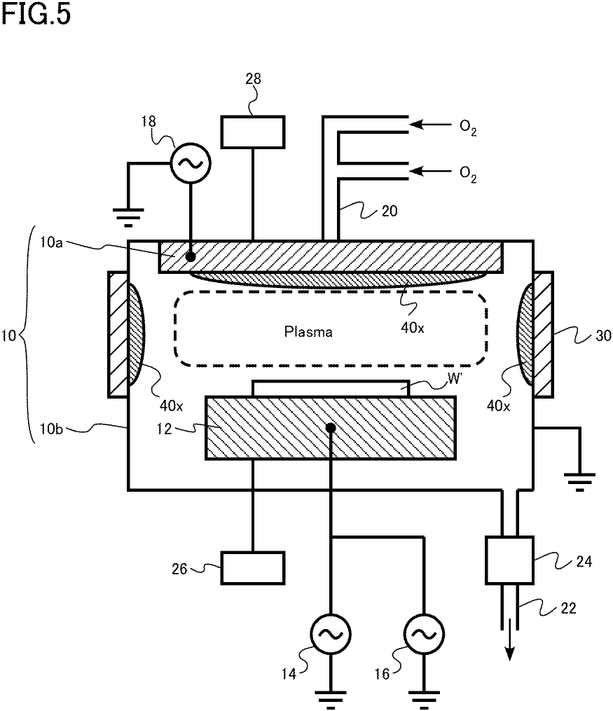

Then, the application of the first high frequency power to the holder 12 by the first high frequency power supply 14 is started. Oxygen plasma is generated by the first high frequency power applied to the holder 12 by the first high frequency power supply 14. By the oxygen plasma, the by-product 40 containing indium adhering to the shower head 10a and the sidewall 10b is oxidized. Due to the oxidation, an oxide 40x containing indium is produced (FIG. 5).

In addition, the application of the second high frequency power to the shower head 10a by the third high frequency power supply 18 is started. The application of the second high frequency power to the shower head 10a is started at the same time as or before or after the application of the first high frequency power to the holder 12.

The oscillation frequency of the second high frequency power is lower than the oscillation frequency of the first high frequency power. In addition, for example, the oscillation frequency of the second high frequency power is the same as or lower than the oscillation frequency of the high frequency power applied to the holder 12 by the second high frequency power supply 16 during the etching processes.

By the second high frequency power applied to the shower head 10a, ions in the oxygen plasma collide with the shower head 10a to heat the shower head 10a. The heating of the shower head 10a promotes the oxidation of the by-product 40 containing indium. The temperature of the shower head 10a is, for example, equal to or more than 120° C. and equal to or less than 150° C.

In addition, the sidewall 10b is heated by using the heater 30. By heating the sidewall 10b, the oxidation of the by-product 40 containing indium is promoted. The temperature of the sidewall 10b is, for example, equal to or more than 120° C. and equal to or less than 150° C.

Then, the application of the first high frequency power to the holder 12 and the application of the second high frequency power to the shower head 10a are stopped.

Then, the supply of oxygen gas into the chamber 10 is stopped.

Then, the supply of hexafluoroacetylacetone (HFAc: C₅H₂F₆O₂) from the gas supply pipe 20 into the chamber 10 is started. Hexafluoroacetylacetone is an example of a second gas containing diketone or hydrocarbon.

Diketone contained in the second gas is, for example, C₅H₈O₂, C₅H₇FO₂, C₅H₆F₂O₂, C₅H₅F₃O₂, C₅H₄F₄O₂, C₅H₃F₅O₂, C₅HF₇O₂, or C₅F₈O₂. Diketone is, for example, β-diketone. Hydrocarbon contained in the second gas is, for example, CH₄ or C₂H₆.

The exhaust device 24 is operated to keep the pressure in the chamber 10 at a predetermined pressure. The heating of the sidewall 10b using the heater 30 is continued.

It is also possible to start the supply of hexafluoroacetylacetone, which is the second gas, after stopping the supply of oxygen gas, which is the first gas, and stop the application of the first high frequency power and the application of the second high frequency power after starting the supply of the second gas.

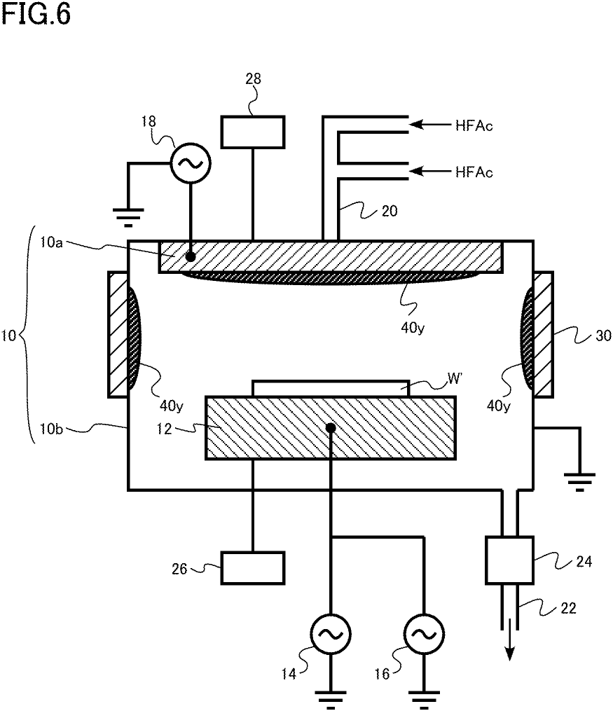

Hexafluoroacetylacetone reacts with the indium oxide 40x to produce a metal complex 40y containing indium (FIG. 6). The produced metal complex 40y is vaporized and exhausted from the gas discharge pipe 22.

Then, the supply of hexafluoroacetylacetone into the chamber 10 is stopped.

Then, for example, the second cooling device 28 is operated to cool the shower head 10a. For example, the shower head 10a is cooled to the temperature of the shower head 10a that is applied when the next etching processes are performed. The shower head 10a is cooled to, for example, a temperature equal to or more than 80° C. and equal to or less than 100° C.

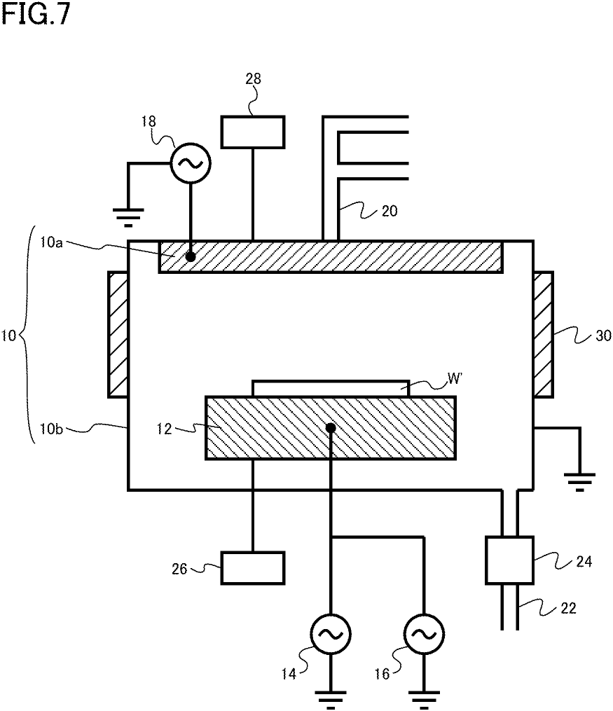

As described above, the cleaning process ends. By the cleaning process, the by-product 40 containing indium that is produced by the etching processes is removed (FIG. 7). Then, the dummy wafer W′ is unloaded from the chamber 10.

For example, if the by-product 40 containing indium is not completely removed in the first cleaning process, the second cleaning process is performed after the first cleaning process ends.

At the beginning of the second cleaning process, the supply of oxygen gas from the gas supply pipe 20 into the chamber 10 is started. The oxygen gas is an example of a third gas containing oxygen (O).

Then, the application of the third high frequency power to the holder 12 by the first high frequency power supply 14 is started. Oxygen plasma is generated by the third high frequency power applied to the holder 12 by the first high frequency power supply 14.

In addition, the application of the fourth high frequency power to the shower head 10a by the third high frequency power supply 18 is started.

In addition, the sidewall 10b is heated by using the heater 30.

Then, the application of the third high frequency power to the holder 12 and the application of the fourth high frequency power to the shower head 10a are stopped.

Then, the supply of oxygen gas into the chamber 10 is stopped.

Then, the supply of hexafluoroacetylacetone (HFAc: C₅H₂F₆O₂) from the gas supply pipe 20 into the chamber 10 is started. Hexafluoroacetylacetone is an example of a fourth gas containing diketone or hydrocarbon.

Then, the supply of hexafluoroacetylacetone into the chamber 10 is stopped.

Then, for example, the second cooling device 28 is operated to cool the shower head 10a.

For example, if the by-product 40 containing indium is not completely removed in the second cleaning process, the third and subsequent cleaning processes are repeated until the by-product 40 containing indium is completely removed.

Next, the function and effect of the semiconductor manufacturing apparatus and the semiconductor device manufacturing method of embodiments will be described.

For example, when a layer containing indium (In), such as an indium tin oxide layer forming a semiconductor device, is etched by using an RIE apparatus, by-products containing indium (In) adhere to the inner surface of the chamber. By-products containing indium adhere to, for example, the surface of the top plate of the chamber or the surface of the sidewall of the chamber.

By-products adhering to the inner surface of the chamber cause the generation of particles, for example. Particles generated in the chamber, for example, reduce the manufacturing yield of semiconductor devices. Therefore, it is necessary to periodically remove by-products adhering to the inner surface of the chamber. That is, it is necessary to periodically perform the chamber cleaning process.

By-products containing indium have a low vapor pressure. In other words, by-products containing indium are less likely to volatilize. For this reason, for example, in order to remove by-products containing indium by heating, a high temperature equal to or more than the temperature exceeding the tolerance of the RIE apparatus is required.

Therefore, for example, a method of opening the chamber and removing by-products containing indium by wet etching or the like can be considered. In this case, however, the time required for the cleaning process increases, and the turnaround time for manufacturing the semiconductor device increases. As a result, for example, the manufacturing cost of the semiconductor device increases.

In the semiconductor manufacturing apparatus and the semiconductor device manufacturing method of embodiments, the by-product 40 containing indium is oxidized by using oxygen plasma. Then, the oxide 40x containing indium produced by oxidation is reacted with a gas containing diketone or hydrocarbon to produce the metal complex 40y containing indium.

For example, when a gas is hexafluoroacetylacetone (HFAc: C₅H₂F₆O₂), the gas reacts with indium oxide (InO₂) to produce In(HFAc)₂, which is a metal complex containing indium.

The metal complex containing indium has a relatively high vapor pressure. In other words, the metal complex containing indium is likely to volatilize. For this reason, for example, the metal complex containing indium can be removed at a temperature equal to or less than 150° C., which is within the tolerance range of the RIE apparatus.

Therefore, the by-product 40 containing indium can be removed without opening the chamber. As a result, for example, the time required for the cleaning process is shortened, and the turnaround time for manufacturing the semiconductor device is reduced.

In the semiconductor device manufacturing method of embodiments, it is preferable to apply the second high frequency power to the shower head 10a between the start of application of the first high frequency power to the holder 12 and the stop of application of the first high frequency power to the holder 12. In other words, when the by-product 40 containing indium is oxidized by oxygen plasma, it is preferable to heat the shower head 10a by applying the second high frequency power to promote the oxidation of the by-product 40 containing indium.

This improves the efficiency of removing the by-product 40 containing indium. Therefore, for example, the time required for the cleaning process is shortened.

In the RIE apparatus 100 of embodiments, since the third high frequency power supply is connected to the shower head 10a, it is possible to apply the second high frequency power to the shower head 10a when the by-product 40 containing indium is oxidized by oxygen plasma.

In the semiconductor device manufacturing method of embodiments, it is preferable to cool the shower head 10a after stopping the supply of hexafluoroacetylacetone. By cooling the shower head 10a, for example, the time required for the cleaning process is shortened.

The RIE apparatus 100 of embodiments preferably includes the second cooling device 28 for cooling the shower head 10a. By providing the second cooling device 28, it is possible to cool the shower head 10a after stopping the supply of gas containing diketone or hydrocarbon.

In the semiconductor device manufacturing method of embodiments, it is preferable that the oscillation frequency of the second high frequency power is lower than the oscillation frequency of the first high frequency power when generating oxygen plasma. Since the impact of ions on the shower head 10a increases, the temperature of the shower head 10a rises.

In the semiconductor device manufacturing method of embodiments, it is preferable that the oscillation frequency of the second high frequency power when generating oxygen plasma is lower than the oscillation frequency of the high frequency power applied to the holder 12 by the second high frequency power supply 16 during the etching processes. Since the impact of ions on the shower head 10a increases, the temperature of the shower head 10a rises. When the supply of hexafluoroacetylacetone starts in a state in which the temperature of the shower head 10a is high, the reactivity becomes high and accordingly, the cleanability is improved.

In the semiconductor device manufacturing method of embodiments, it is preferable to heat the sidewall 10b between the start of the supply of hexafluoroacetylacetone and the stop of the supply of hexafluoroacetylacetone. By increasing the temperature of the sidewall 10b, the reaction between the indium oxide 40x and hexafluoroacetylacetone is promoted.

Therefore, the efficiency of removing the by-product 40 containing indium is improved. As a result, for example, the time required for the cleaning process is shortened.

In the semiconductor device manufacturing method of embodiments, it is preferable to start the supply of hexafluoroacetylacetone after stopping the supply of oxygen gas and stop the application of the first high frequency power and the application of the second high frequency power after starting the supply of hexafluoroacetylacetone. When hexafluoroacetylacetone is decomposed by plasma, the reaction for forming a metal complex is reduced and accordingly, the removal efficiency is lowered. Before the temperature of the surface of the shower head 10a drops, the reaction between the indium oxide 40x and hexafluoroacetylacetone is started.

Therefore, by stopping the generation of plasma so that the reaction occurs by heat, the efficiency of removing the by-product 40 containing indium is improved. As a result, for example, the time required for the cleaning process is shortened.

In the semiconductor device manufacturing method of embodiments, the diketone contained in the second gas is preferably β-diketone. The use of β-diketone promotes the reaction of forming the metal complex 40y containing indium.

Therefore, the efficiency of removing the by-product 40 containing indium is improved. As a result, for example, the time required for the cleaning process is shortened.

As described above, according to the semiconductor manufacturing apparatus and the semiconductor device manufacturing method of embodiments, it is possible to remove by-products containing indium.

Although the case where the semiconductor manufacturing apparatus used in the semiconductor device manufacturing method of embodiments is a capacitively coupled plasma apparatus (CCP apparatus) has been described as an example, the semiconductor manufacturing apparatus used in the semiconductor device manufacturing method of embodiments is not limited to the CCP apparatus. For example, it is also possible to use an inductively coupled plasma apparatus (ICP apparatus).

In the semiconductor manufacturing apparatus of embodiments, the case where the first high frequency power supply 14 applies high frequency power to the holder 12 has been described as an example. However, the first high frequency power supply 14 may apply high frequency power to the shower head 10a.

In addition, in embodiments, the case where the top plate is the shower head 10a has been described as an example, but the top plate may have a structure other than the shower head. For example, the top plate may be an electrode separated from the gas supply pipe 20.

While certain embodiments have been described, these embodiments have been presented by way of example only, and are not intended to limit the scope of the inventions. Indeed, the semiconductor manufacturing apparatus and the semiconductor device manufacturing method described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor manufacturing apparatus, comprising:
a chamber including a top plate and a sidewall;
a holder provided in the chamber holding a substrate;
a first high frequency power supply applying high frequency power to the holder or the top plate;
a second high frequency power supply applying high frequency power to the holder;
a third high frequency power supply applying high frequency power to the top plate;
a gas supply pipe supplying a gas to the chamber; and
a gas discharge pipe discharging a gas from the chamber.

2. The semiconductor manufacturing apparatus according to claim 1, further comprising:
a cooling device cooling the top plate.

3. The semiconductor manufacturing apparatus according to claim 1,
wherein an oscillation frequency of the first high frequency power supply is higher than an oscillation frequency of the second high frequency power supply, and the oscillation frequency of the first high frequency power supply is higher than an oscillation frequency of the third high frequency power supply.

4. The semiconductor manufacturing apparatus according to claim 3,
wherein the oscillation frequency of the third high frequency power supply is lower than the oscillation frequency of the second high frequency power supply.

5. The semiconductor manufacturing apparatus according to claim 1, further comprising:
a heater heating the sidewall of the chamber.

6. The semiconductor manufacturing apparatus according to claim 1,
wherein the gas supply pipe is configured to supply a gas containing diketone or hydrocarbon and a gas containing oxygen into the chamber.

7. A semiconductor device manufacturing method, comprising:
loading a substrate having a first layer containing indium (In) into a chamber of a reactive ion etching apparatus including the chamber and a holder provided in the chamber to hold a substrate, the chamber including a top plate and a sidewall;
placing the substrate on the holder;
performing etching processes to etch the first layer after placing the substrate;
unloading the substrate out of the chamber;
starting supply of a first gas containing oxygen (O) into the chamber after unloading the substrate;
starting application of first high frequency power to the holder or the top plate to generate oxygen plasma in the chamber after unloading the substrate;
stopping the application of the first high frequency power;
stopping the supply of the first gas;
starting supply of a second gas containing diketone or hydrocarbon into the chamber; and
stopping the supply of the second gas.

8. The semiconductor device manufacturing method according to claim 7, further comprising:
performing application of second high frequency power to the top plate between the starting application of the first high frequency power and the stopping application of the first high frequency power.

9. The semiconductor device manufacturing method according to claim 8,
wherein an oscillation frequency of the second high frequency power is lower than an oscillation frequency of the first high frequency power.

10. The semiconductor device manufacturing method according to claim 7, further comprising:
cooling the top plate after the stopping the supply of the second gas.

11. The semiconductor device manufacturing method according to claim 7, further comprising:
heating the sidewall between the starting supply of the second gas and the stopping supply of the second gas.

12. The semiconductor device manufacturing method according to claim 7,
wherein the diketone is β-diketone.

13. The semiconductor device manufacturing method according to claim 8,
wherein the starting supply of the second gas is conducted after the stopping the supply of the first gas, and the stopping application of the first high frequency power and stopping the application of the second high frequency power are conducted after the starting supply of the second gas.

14. The semiconductor device manufacturing method according to claim 7,
wherein the oxygen plasma oxidizes a by-product containing indium (In) adhering to the top plate.

15. The semiconductor device manufacturing method according to claim 7,
wherein a metal complex containing indium (In) is produced by the second gas.

16. The semiconductor device manufacturing method according to claim 8,
wherein the top plate is heated by the application of the second high frequency power to the top plate.

17. The semiconductor device manufacturing method according to claim 7, further comprising:
staring supply of a third gas containing oxygen (O) into the chamber after the stopping the supply of the second gas;
starting application of third high frequency power to the holder or the top plate to generate oxygen plasma in the chamber;
stopping the application of the third high frequency power;
stopping the supply of the third gas;
starting supply of a fourth gas containing diketone or hydrocarbon into the chamber; and
stopping the supply of the fourth gas.
